(19) United States
(12) Patent Application Publication
(10) Pub. No.: US 2025/0275360 A1
(43) Pub. Date: Aug. 28, 2025

(54) DISPLAY DEVICE

(71) Applicant: LG Display Co., Ltd., Seoul (KR)

(72) Inventor: Myeonghak Hyun, Paju-si (KR)

(73) Assignee: LG Display Co., Ltd., Seoul (KR)

(21) Appl. No.: 18/886,050

(22) Filed: Sep. 16, 2024

(30) Foreign Application Priority Data
Feb. 28, 2024 (KR) 10-2024-0028711

(51) Int. Cl. H10K 59/121; H10K 59/126

(52) U.S. Cl. CPC H10K 59/1213; H10K 59/126

(57) ABSTRACT

Disclosed is a display device in which irradiation of ultraviolet rays to an active layer of each of some of thin-film transistors is reduced due to a patterned area formed in a lower surface of a substrate and in an area overlapping each of some of the thin-film transistors. Thus, negative shift of a threshold voltage of the thin-film transistor is reduced.

### CROSS-REFERENCE TO RELATED APPLICATION

This application claims priority from Korean Patent Application No. 10-2024-0028711, filed on Feb. 28, 2024 in the Korean Intellectual Property Office, and all the benefits accruing therefrom under 35 U.S.C. 119, the contents of which in its entirety are herein incorporated by reference.

### FIELD

The present disclosure relates to a display device that may effectively block ultraviolet rays.

### BACKGROUND

A display device is used in a variety of devices such as televisions, monitors, smart phones, tablet PCs, laptops, and wearable devices.

The display device may display an image through a number of pixels included in a display area.

Recently, research is being conducted on a transparent display device that allows a user to see objects or backgrounds located in rear of the display device.

The transparent display device may include a transmissive area that transmits incident light therethrough and a pixel area that emits light to create an image.

The user may see the objects or background located in rear of the transparent display device through the transmissive area.

### SUMMARY

When ultraviolet (UV) rays of external light in rear of the display device are incident to the display device, an active layer of a thin-film transistor may be exposed to the ultraviolet light.

When the active layer of the thin-film transistor is exposed to the ultraviolet rays, the active layer is activated and the carrier increases, such that a negative shift in a threshold voltage of the thin-film transistor may occur.

In order to prevent the active layer of the thin-film transistor from being exposed to the ultraviolet rays, a scheme of placing a UV ray-blocking film on a bottom of a substrate may be used.

However, when using the UV ray-blocking film, not only does a cost increase, but there is a problem in that transmittance of the transparent display device decreases.

Additionally, a scheme of blocking the ultraviolet rays placing a light-blocking layer under the active layer of the thin-film transistor may be used.

However, when a size of the thin-film transistor is small, there may not be enough space in which the light-blocking layer is disposed under the active layer. Therefore, in some of thin-film transistors, it may be difficult to form the light-blocking layer under the active layer.

A defective bright point or a defective dark point may occur in some pixels of the display device. In this case, the pixel having the defective bright point or the defective dark point may be repaired by irradiating ultraviolet laser to a back of the display device to cut a wiring to the defective pixel.

However, when a UV ray-blocking member such as a UV ray-blocking film is disposed on an entire back surface of the substrate, the UV-blocking member should be removed for the pixel repair.

Accordingly, through various experiments, the inventors of the present disclosure have invented a transparent display device that may reduce decline in transmittance of the transparent display device while minimizing external ultraviolet rays irradiated to the active layer of the thin-film transistor.

A purpose according to an embodiment of the present disclosure is to provide a display device that may reduce the negative shift of the threshold voltage of the thin-film transistor.

In addition, a purpose according to an embodiment of the present disclosure is to provide a transparent display device that may reduce decrease in transmittance of the transparent display device.

In addition, a purpose according to an embodiment of the present disclosure is to provide a display device that may freely use a scheme of repairing a defective pixel by irradiating ultraviolet laser through the bottom of the substrate without any special restrictions.

In addition, a purpose according to an embodiment of the present disclosure is to provide a display device that may reduce a cost related to an ultraviolet ray blocking member.

In addition, a purpose according to an embodiment of the present disclosure is to provide a display device capable of implementing Uni-material technology via simplification of a part material.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure includes a substrate including a plurality of pixels, each including a plurality of sub-pixels; and a first thin-film transistor and a second thin-film transistor included in each of the sub-pixels, wherein a non-patterned area vertically overlapping the first thin-film transistor and a patterned area vertically overlapping the second thin-film transistor are formed in a lower surface of the substrate.

A display device according to an embodiment of the present disclosure includes a substrate including a display area and a non-display area; a plurality of sub-pixels arranged in the display area; and a plurality of thin-film transistor included in each of the sub-pixels, wherein a lower surface of the substrate includes a patterned area formed by selectively patterning a portion of the lower surface in an area corresponding to at least one of the plurality of thin-film transistors.

According to an embodiment of the present disclosure, irradiation of ultraviolet rays to the active layer of each of some of the thin-film transistors may be reduced due to the patterned area formed in the lower surface of the substrate and in an area overlapping each of some of the thin-film transistors. Thus, negative shift of the threshold voltage of the thin-film transistor may be reduced.

Further, according to an embodiment of the present disclosure, the patterned area is formed not in the entire area of the lower surface of the substrate, but only in a partial area thereof. Thus, the decrease in transmittance of the transparent display device due to the presence of the patterned area may be minimized.

In addition, in the display device according to an embodiment of the present disclosure, the patterned area formed in the partial area of the lower surface of the substrate may block external ultraviolet rays, such that there is no need to attach a separate UV-blocking member to an entire area of the substrate. Thus, a scheme of repairing the defective pixel by irradiating the ultraviolet laser through the bottom of the substrate may be freely used without any special restrictions.

Further, according to an embodiment of the present disclosure, the patterned area formed in the partial area of the lower surface of the substrate may block external ultraviolet ray. Thus, there is no need to attach a separate UV blocking member, such that a cost for the UV blocking member may be greatly reduced.

Moreover, according to an embodiment of the present disclosure, the patterned area formed in the partial area of the lower surface of the substrate may block external ultraviolet rays. Thus, there is no need to attach a separate UV blocking member, such that Uni-materialization technology may be implemented via simplification of a component material.

Effects of the present disclosure are not limited to the effects mentioned above, and other effects not mentioned will be clearly understood by those skilled in the art from the descriptions below.

Additional features and aspects of the present disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure.

FIG. 1 is a schematic plan view of a display device according to an embodiment of the present disclosure.

FIG. 2 is a circuit diagram of one sub-pixel of a display device according to an embodiment of the present disclosure.

FIGS. 3-4 show a patterned area formed in each of a non-display area and a display area of a display device according to an embodiment of the present disclosure.

FIG. 5 is a cross-sectional view of one pixel of a display device according to an embodiment of the present disclosure.

FIGS. 6-7 are enlarged cross-sectional views of first and second patterns, respectively.

FIG. 8 is a plan view showing an active layer and a patterned area.

FIGS. 9 to 21 are process diagrams for forming a first pattern and a second pattern in a substrate of a display device according to an embodiment of the present disclosure.

FIG. 22 shows a first pattern and a second pattern formed in a substrate of a display device according to an embodiment of the present disclosure.

FIGS. 23 to 26 show recesses formed in a substrate of a display device according to various embodiments of the present disclosure, respectively.

### DETAILED DESCRIPTIONS

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, dimensions, areas, lengths, thicknesses, ratios, angles, numbers, and the like, which are illustrated in the drawings to describe various example embodiments of the present disclosure, are merely given by way of example. Therefore, the present disclosure is not limited to such illustrated details in the drawings. Like reference numerals generally denote like elements throughout the specification, unless otherwise specified. For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

In construing an element, the element should be construed as including an error or tolerance range even where no explicit description of such an error or tolerance range is provided.

Further, as used herein, when a layer, film, region, plate area, or the like is be disposed “on” or “on a top” of another layer, film, region, plate area, or the like, the former may directly contact the latter or still another layer, film, region, plate area, or the like may be disposed between the former and the latter. As used herein, when a layer, film, region, plate area, or the like is directly disposed “on” or “on a top” of another layer, film, region, plate area, or the like, the former directly contacts the latter and still another layer, film, region, plate area, or the like is not disposed between the former and the latter. Further, as used herein, when a layer, film, region, plate area, or the like is disposed “below” or “under” another layer, film, region, plate area, or the like, the former may directly contact the latter or still another layer, film, region, plate area, or the like may be disposed between the former and the latter. As used herein, when a layer, film, region, plate area, or the like is directly disposed “below” or “under” another layer, film, region, plate area, or the like, the former directly contacts the latter and still another layer, film, region, plate area, or the like is not disposed between the former and the latter.

Where a temporal relationship is described using such a term as “after,” “subsequent(ly),” “next,” “before,” or the like, it may include a non-consecutive or non-continuous case unless it is used with a more limiting term like “immediately” or “directly.”

Although terms “first,” “second,” and the like may be used herein to describe various elements, these elements should not be interpreted to be limited by these terms as they are not used to define a particular essence, order, sequence, precedence, or number of such elements. These terms are used only to refer one element separately from another. For example, a first element could be termed a second element, and a second element could similarly be termed a first element, without departing from the scope of the present disclosure.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

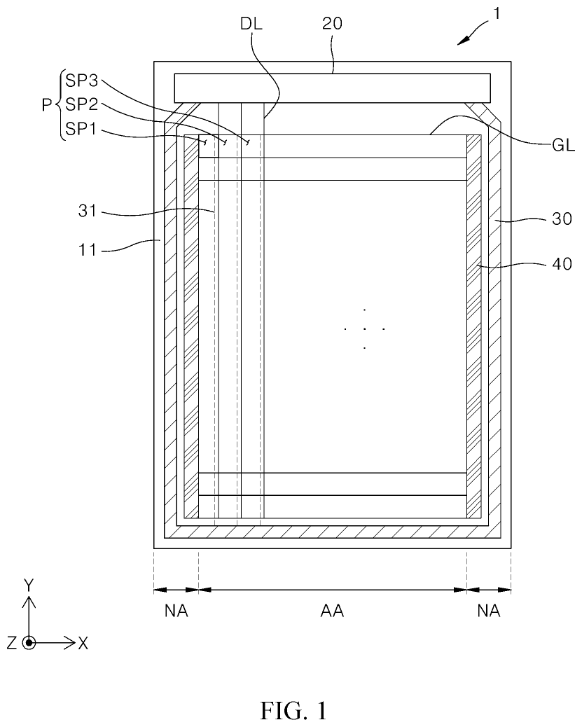

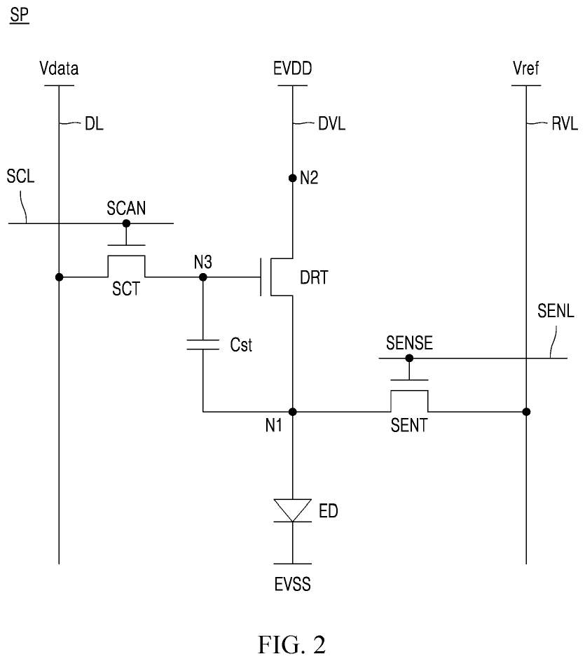

Hereinafter, with reference to FIG. 1 to FIG. 2, a display device according to an embodiment of the present disclosure will be described in detail.

FIG. 1 is a schematic plan view of a display device according to an example of the present disclosure.

An example in which a display device 1 is embodied as an organic electroluminescent display device (organic light-emitting diode display device) is described below. However, example embodiments of the present disclosure are not limited thereto.

The display device 1 may include a substrate 11 including a display area AA and a non-display area NA surrounding the display area AA.

In on the display area AA of the substrate 11, a plurality of data lines DL extending in a first direction and a plurality of gate lines GL extending in a second direction intersecting the first direction may be arranged.

Each of sub-pixels SP1, SP2, and SP3 may be disposed in each of intersections of the data lines DL and the gate lines GL.

The sub-pixels SP1, SP2, and SP3 may emit light of the same color, such as white (W) light, or red (R), green (G), or blue (B) light, or may emit light beams of different colors.

A combination of the plurality of sub-pixels SP1, SP2, and SP3 as described above may constitute one pixel P.

The plurality of sub-pixels SP1, SP2, and SP3 may be arranged in a plurality of rows and columns in a matrix format.

As used herein, the first direction may be a column direction and may be defined as a Y-axis direction, and the second direction may be a row direction and may be defined as a X-axis direction.

A number of lines and pads that supply various signals and powers to the pixel may be disposed on the non-display area NA of the substrate 11.

A data driver (D-IC) 20 may be disposed in one side area of the non-display area NA.

The data driver 20 may apply a data signal to the data line DL, and may apply a driving voltage such as a high potential voltage VDD or a low potential voltage VSS to the pixel P.

A power line 30 may extend along an edge of the display area AA and in a-side area of the non-display area NA other than the side area in which the data driver 20 is disposed.

For example, a gate driver 40 that applies a gate signal to the gate line GL may be disposed in the non-display area NA and located on each of both opposing sides of the display area AA. The power line may be 30 capable of applying a voltage to an anode electrode or a cathode electrode in the pixel P may extend along an outer edge of the gate driver 40 and in the non-display area NA.

The gate driver 40 formed on the first substrate 11 in a GIP (Gate-In-Panel) scheme may be named a GIP driver.

The power line 30 may include a low-potential voltage line capable of applying a low-potential voltage VSS to the cathode electrode of the pixel P. However, embodiments of the present disclosure are not limited thereto. The power line 30 may further include a high-potential voltage line capable of applying a high-potential voltage VDD to a thin-film transistor of the pixel P.

A plurality of power connection lines 31 may be disposed in the display area AA and may be electrically connected to and disposed between the power line 30 to the plurality of sub-pixels SP1, SP2, and SP3 and may apply the low potential voltage to the plurality of sub-pixels SP1, SP2, and SP3.

For example, the plurality of power connection lines 31 may extend in the first direction in which the plurality of data lines DL extend by an equal length.

FIG. 2 is a circuit diagram of one sub-pixel of a display device according to an example of the present disclosure.

Each of the sub-pixels SP1, SP2, and SP3 of the display device 10 according to an embodiment of the present disclosure may include a light-emitting element ED, a driving transistor DRT, a scan transistor SCT, a sensing transistor SENT, and a storage capacitor Cst.

The light-emitting element ED may include a light-emitting layer EL located between a pixel electrode and a common electrode.

The pixel electrode of the light-emitting element ED may be an electrode disposed in each of the sub-pixel SP1, SP2, and SP3, and the common electrode may be an electrode commonly disposed across all of the sub-pixels SP1, SP2, and SP3.

The pixel electrode may be an anode electrode AND and the common electrode may be a cathode electrode CAT. However, embodiments of the present disclosure are not limited thereto. The pixel electrode may be a cathode electrode CAT and the common electrode may be an anode electrode AND.

For example, the light-emitting element ED may be embodied as an organic light-emission diode (OLED), a light-emission diode (LED), or a quantum dot light-emitting element.

The driving transistor DRT may be a transistor for driving the light-emitting element ED, and may include a first node N1, a second node N2, and a third node N3.

The first node N1 of the driving transistor DRT may be a source node (a source electrode) or a drain node (a drain electrode) of the driving transistor DRT, and may be electrically connected to the pixel electrode PE of the light-emitting element ED.

The second node N2 of the driving transistor DRT may be the drain electrode or the source electrode of the driving transistor DRT, and may be electrically connected to a driving voltage line DVL that supplies a driving voltage EVDD.

The third node N3 of the driving transistor DRT may be a gate electrode of the driving transistor DRT, and may be electrically connected to a source node or a drain node of the scan transistor SCT.

The scan transistor SCT may be controlled based on a scan gate signal SCAN which is a type of a gate signal, and may be connected to and disposed between the third node N3 of the driving transistor DRT and the data line DL.

The scan transistor SCT may be turned on or turned off based on the scan gate signal SCAN supplied from a scan gate line SCL as a type of the gate line GL, and may control connection between the data line DL and the third node N3 of the driving transistor DRT.

The scan transistor SCT may be turned on based on the scan gate signal SCAN having a turn-on level voltage, and thus may transmit the data voltage Vdata supplied from the data line DL to the third node N3 of the driving transistor DRT.

The storage capacitor Cst may be connected to and disposed between the third node N3 and the first node N1 of the driving transistor DRT.

The storage capacitor Cst may be charged with charges corresponding to a voltage difference between voltages of two opposing ends thereof and plays the role of maintaining the voltage difference for a set frame time.

Accordingly, the sub-pixels SP1, SP2, and SP3 may emit light during the set frame time.

The sensing transistor SENT may be controlled based on a sensing gate signal SENSE which is a type of the gate signal, and may be connected to and disposed between the first node N1 of the driving transistor DRT and a reference voltage line RVL.

The sensing transistor SENT may be turned on or turned off based on the sensing gate signal SENSE supplied from a sensing gate line SENL as another type of the gate line GL, and may control connection between the reference voltage line RVL and the first node N1 of the driving transistor DRT.

The sensing transistor SENT may be turned on based on the sensing gate signal SENSE having a turn-on level voltage, and thus may transmit a reference voltage Vref supplied from the reference voltage line RVL to the first node N1 of the driving transistor DRT.

Additionally, the sensing transistor SENT may be turned on based on the sensing gate signal SENSE having a turn-on level voltage, and thus may transmit a voltage of the first node N1 of the driving transistor DRT to the reference voltage line RVL.

A function of the sensing transistor SENT to transfer the voltage of the first node N1 of the driving transistor DRT to the reference voltage line RVL may be used to sense characteristics of the sub-pixel SP.

In this case, the voltage transmitted to the reference voltage line RVL may be a voltage used for calculating the characteristics of each of the sub-pixels SP1, SP2, and SP3, or a voltage to which the characteristics of each of the sub-pixel SP1, SP2, and SP3 are applied.

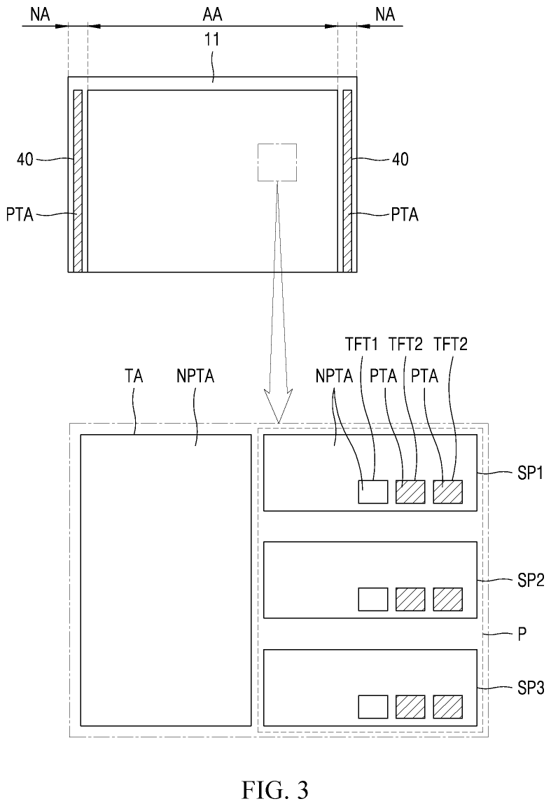

Hereinafter, with reference to FIG. 3 to FIG. 8, a display device according to an embodiment of the present disclosure will be described in detail.

A first substrate 11 may include silicon oxide (SiO₂) and, for example, may be a glass substrate.

A display area AA disposed on the first substrate 11 may include a plurality of pixels P, and each pixel P may include a plurality of sub-pixels SP1, SP2, and SP3.

In this case, the first sub-pixel SP1 may be a red sub-pixel, the second sub-pixel SP2 may be a green sub-pixel, and the third sub-pixel SP3 may be a blue sub-pixel.

The remaining area of the display area AA other than an area where the sub-pixels SP1, SP2, and SP3 are disposed may be a transmissive area TA through which light can transmit.

The display device 1 including the transmissive area TA may be a transparent display device.

Each of the sub-pixels SP1, SP2, and SP3 may include a first thin-film transistor TFT1 and one or more second thin-film transistors TFT2.

The first thin-film transistor TFT1 may be a driving thin-film transistor acting as the driving transistor DRT.

Additionally, the second thin-film transistor TFT2 may act as a scanning thin-film transistor such as the scanning transistor SCT, or a sensing thin-film transistor such as the sensing transistor SENT.

In the display area AA, a patterned area PTA may be formed in a lower surface of the first substrate 11 and in an area corresponding to the second thin-film transistor TFT2.

That is, the second thin-film transistor TFT2 and the patterned area PTA may be positioned to overlap each other in a vertical direction.

Further, in the display area AA, a non-patterned area NPTA may be formed in the lower surface of the first substrate 11 and in an area corresponding to the first thin-film transistor TFT1.

That is, the first thin-film transistor TFT1 and the non-patterned area NPTA may be positioned to overlap each other in the vertical direction.

The patterned area PTA as defined in the present disclosure may mean an area in which the lower surface of the first substrate 11 is patterned into a predetermined pattern.

In this case, the predetermined pattern may be a regular pattern. However, embodiments of the present disclosure are not limited thereto, and the predetermined pattern may be an irregular pattern.

The non-patterned area NPTA refers to an area other than the patterned area PTA, and may refer to an area in which the lower surface of the first substrate 11 is not patterned.

An area of the lower surface of the first substrate 11 and in an area corresponding to the non-patterned area NPTA may have a flat surface.

The patterned area PTA formed in the display area AA as described above may be formed by selectively patterning the first substrate 11 in the area corresponding to the second thin-film transistor TFT2 among the plurality of thin-film transistors.

Accordingly, a portion of the display area AA other than the area corresponding to the second thin-film transistor TFT2 may be the non-patterned area NPTA.

In one example, a patterned area PTA may also be formed in the lower surface of the first substrate 11 and in an area corresponding to the gate driver 40 disposed in the non-display area NA.

For example, referring to FIG. 3, the patterned area PTA may be formed in the lower surface of the first substrate 11 and in an area corresponding to an entire area of the gate driver 40.

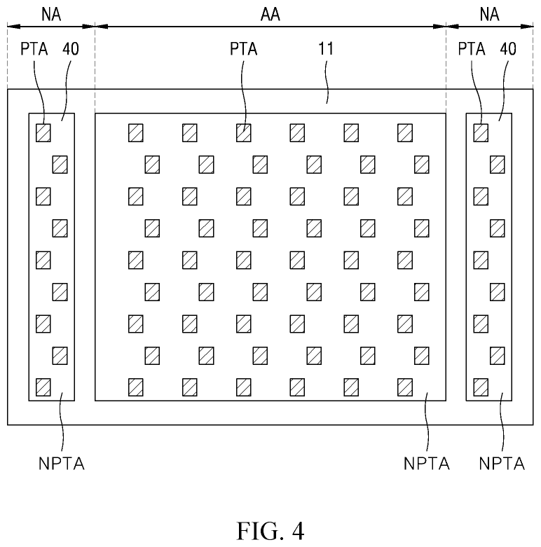

However, embodiments of the present disclosure are not limited thereto. Referring to FIG. 4, the patterned area PTA may be selectively formed only in an area corresponding to a partial area of the gate driver 40.

For example, one or more third thin-film transistor TFT3 may be disposed in the gate driver 40. A patterned area PTA may be formed in the lower surface of the first substrate 11 and in an area corresponding to the third thin-film transistor TFT3.

The third thin-film transistor TFT3 may be a GIP driving thin-film transistor. However, embodiments of the present disclosure are not limited thereto.

The gate driver 40 may include a shift register and a level shifter, and the third thin-film transistor TFT3 may receive a gate start pulse, a gate shift clock signal, and a gate output enable signal from a timing controller and may sequentially apply the gate signal to the gate lines GLs.

A light-blocking layer LS may be formed on the first substrate 11.

The light-blocking layer LS may block external light such as ultraviolet rays incident through the lower surface of the first substrate 11 and protect the active layer of the thin-film transistor.

Therefore, the light-blocking layer LS may be positioned to overlap the active layer of the thin-film transistor in the vertical direction.

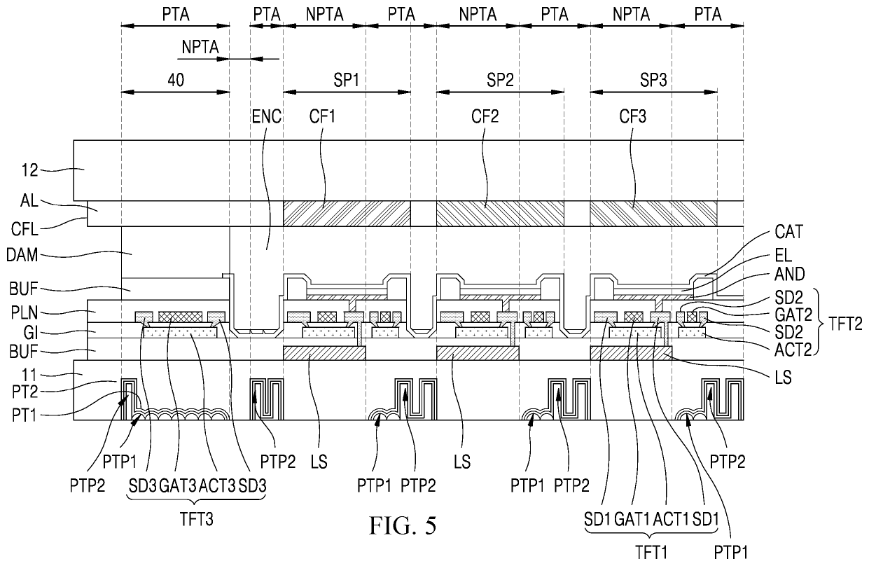

The vertical direction in FIG. 5 may refer to a Z-axis direction.

The light-blocking layer LS is formed to have a larger area than that of the active layer, and may effectively prevent the light from being incident into the active layer.

The light-blocking layer LS may be disposed only under some of the thin-film transistors.

For example, the light-blocking layer LS may be disposed under the first thin-film transistor TFT1 and may be disposed to overlap the first thin-film transistor TFT1 in the vertical direction.

However, the light-blocking layer LS may not be disposed under the second thin-film transistor TFT2 and the third thin-film transistor TFT3, and accordingly, the light-blocking layer LS may be disposed so as not to overlap the second thin-film transistor TFT2 and the third thin-film transistor TFT3 in the vertical direction.

Additionally, the light-blocking layer LS may be positioned to overlap the non-patterned area NPTA of the first substrate 11 in the vertical direction, but not to overlap the patterned area PTA in the vertical direction.

In one example, the light-blocking layer LS may be made of one selected from the group consisting of molybdenum (Mo), titanium (Ti), and copper (Cu_, or an alloy thereof, and may be formed as a single layer or a stack of multiple layers.

A buffer layer BUF may be disposed on the light-blocking layer LS.

The buffer layer BUF may be composed of a single or double layer made of silicon oxide (SiOx) or silicon nitride (SiNx). However, embodiments of the present disclosure are not limited thereto.

On the buffer layer BUF and in the display area AA, a first active layer ACT1 of the first thin-film transistor TFT1, a second active layer ACT2 of the second thin-film transistor TFT2, and a third active layer of the third thin-film transistor TFT3 layer ACT3 may be disposed.

Each of the first active layer ACT1, the second active layer ACT2, and the third active layer ACT3 may include an oxide semiconductor material.

Accordingly, the first active layer ACT1 may be positioned to overlap the light-blocking layer LS in the vertical direction, while the second active layer ACT2 and the third active layer ACT3 may be positioned so as not to overlap the light-blocking layer LS in the vertical direction.

A width in a left-right direction of the second active layer ACT2 may be smaller than a width in the left-right direction of the first active layer ACT1.

Accordingly, it may be difficult to provide a sufficient space in which the light-blocking layer LS is to be formed under the second active layer ACT2, compared to the first active layer ACT1.

A gate insulating layer GI may be disposed on the first active layer ACT1, the second active layer ACT2, and the third active layer ACT3.

The gate insulating layer GI may be composed of a single or double layer made of silicon oxide (SiOx) or silicon nitride (SiNx). However, embodiments of the present disclosure are not limited thereto.

A first gate electrode GAT1, a second gate electrode GAT2, and a third gate electrode GAT3 may be disposed on the gate insulating layer GI.

The first gate electrode GAT1, the second gate electrode GAT2, and the third gate electrode GAT3 may be positioned to overlap with the first active layer ACT1, the second active layer ACT2, and the third active layer ACT3 in the vertical direction, respectively.

Further, a pair of first source/drain electrodes SD1 which are respectively connected to one side and the other side of the first active layer ACT1 via contact holes extending through the gate insulating layer GI, a pair of second source/drain electrodes SD2 respectively connected to one side and the other side of the second active layer ACT2 via contact holes extending through the gate insulating layer GI, and a pair of third source/drain electrodes SD3 respectively connected to one side and the other side of the third active layer ACT3 via contact holes extending through the gate insulating layer GI may be disposed on the gate insulating layer GI.

In this case, one of the pair of first source/drain electrodes SD1 may be electrically connected to the light-blocking layer LS via a contact hole extending through the gate insulating layer GI and the buffer layer BUF.

As the first source drain electrode SD1 and the light-blocking layer LS are electrically connected to each other in this way, the light-blocking layer LS may be prevented from functioning as a parasitic capacitor.

FIG. 5 shows an example in which the gate electrode and the source drain electrode are formed in the same layer. However, embodiments of the present disclosure are not limited thereto. Based on an inorganic layer such as the interlayer insulating layer, the gate electrode and the source drain electrode may be disposed in different layers.

The first thin-film transistor TFT1 may be composed of the first active layer ACT1, the first gate electrode GAT1, and the pair of first source/drain electrode SD1. The second thin-film transistor TFT2 may be composed of the second active layer ACT2, the second gate electrode GAT2, and the pair of second source/drain electrodes SD2. The third thin-film transistor TFT3 may be composed of the third active layer ACT3, the third gate electrode GAT3, and the pair of third source/drain electrodes SD3.

A planarization layer PLN may be disposed on the gate electrodes GAT1, GAT2, and GAT3 and the source/drain electrodes SD1, SD2, and SD3.

The planarization layer PLN may serve to planarize a surface on top of the first thin-film transistor TFT1, the first thin-film transistor TFT1, and the first thin-film transistor TFT1.

For example, the planarization layer PLN may include an organic insulating material such as acryl resin, epoxy resin, phenolic resin, polyamide resin, or polyimide resin.

The light-emitting element ED may be disposed on the planarization layer PLN.

The light-emitting element ED corresponding to each of the sub-pixels SP1, SP2, and SP3 may include an anode electrode AND, a light-emitting layer EL, and a cathode electrode CAT.

The anode electrode AND may be disposed on the planarization layer PLN.

The anode electrode AND may be electrically connected to the first source/drain electrode SD1 via a contact hole extending through the planarization layer PLN.

A bank BNK may be disposed on the planarization layer PLN.

The bank BNK may serve to distinguish adjacent sub-pixels from each other, and may prevent light beams of different colors output from adjacent sub-pixels from being mixed with each other.

The bank BNK may be positioned to cover an edge of the anode electrode AND.

In one example, the bank BNK may include an organic insulating film made of, for example, polyimide or epoxy.

The light-emitting layer EL may be disposed on the anode electrode AND.

In one example, the light-emitting layer EL may be an organic light-emitting layer.

The respective light-emitting layers EL of the sub-pixels SP1, SP2, and SP3 may include different organic materials that emit light of different colors.

For example, the light-emitting layer EL may emit light of one color among red, green, blue, and white.

Additionally, the light-emitting layer EL may be made of an organic material that emits white light, and the whit light may be changed into light of one color among red, green, or blue through a color filter.

The light-emitting layer EL may be formed between adjacent banks BNK so as to cover the anode electrode AND, and may extend to cover a portion of an upper surface of the bank BNK.

The cathode electrode CAT may be disposed on the light-emitting layer EL.

The cathode electrode CAT may be disposed across the entirety of the display area AA so as to cover the plurality of sub-pixels SP1, SP2, and SP3.

An encapsulation layer ENC may be formed on the cathode electrode CAT.

In one example, the encapsulation layer ENC may have a structure in which an inorganic encapsulation layer, an organic encapsulation layer, and an inorganic encapsulation layer are sequentially stacked.

The organic encapsulation layer may include at least one organic insulating material selected from epoxy, polyimide, polyethylene, or acrylate. The inorganic encapsulating layer may include at least one inorganic insulating material of silicon oxide (SiOx) and silicon nitride (SiNx).

The encapsulation layer ENC may be located on an inner surface of a dam DAM.

For example, the bank BNK may be formed on the planarization layer PLN and in an area corresponding to the gate driver 40, and the dam DAM may be formed on the bank BNK.

A color filter layer CFL may be disposed on the encapsulation layer ENC.

The color filter layer CFL may include a first color filter CF1 disposed so as to correspond to the first sub-pixel SP1, a second color filter CF2 disposed so as to correspond to the second sub-pixel SP2, and a third color filter CF3 disposed so as to correspond to the third sub-pixel SP3.

A second substrate 12 may be disposed on the color filter layer CFL.

In one example, the second substrate 12 may be a glass substrate.

The color filter layer CFL may include an adhesive layer AL. The second substrate 12 disposed on one surface of the color filter layer CFL may face and be bonded to the first substrate 11 via the adhesive layer AL.

Hereinafter, the patterned area PTA formed in the lower surface of the first substrate 11 will be described in more detail.

For example, the patterned area PTA formed in the lower surface of the first substrate 11 may be formed to have a pattern shape depressed toward the second thin-film transistor TFT2 using an etching process.

A first pattern PT1 and a second pattern PT2 may be formed in the lower surface of the first substrate 11 and in an area corresponding to the patterned area PTA.

A first pattern layer PTL1 and a second pattern layer PTL2 may be sequentially stacked in the lower surface of the first substrate 11 and in an area corresponding to the patterned area PTA.

That is, the first pattern layer PTL1 is formed in the lower surface of the first substrate 11, and the second pattern layer PTL2 is formed on a lower surface of the first pattern layer PTL1.

The first pattern PT1 of the first substrate 11, and the first pattern layer PTL1 and the second pattern layer PTL2 sequentially stacked under the first pattern PT1 may constitute a first pattern structure PTP1 of the patterned area PTA.

In addition, the second pattern PT2 of the first substrate 11, and the first pattern layer PTL1 and the second pattern layer PTL2 sequentially stacked under the second pattern PT2 may constitute a second pattern structure PTP2 of the patterned area PTA.

The first pattern structure PTP1 or the second pattern structure PTP2 may be formed in the patterned area PTA, or both the first pattern structure PTP1 and the second pattern structure PTP2 may be formed.

In one example, the first pattern layer PTL1 may include one or more of indium tin oxide (ITO), indium zinc oxide (IZO), and zinc oxide (ZnO).

Additionally, the second pattern layer PTL2 may include silicon oxide (SiOx) and, for example, may include silicon dioxide (SiO₂) such as the glass.

The first pattern layer PTL1 may be made of a material with a higher refractive index than that of each of the first substrate 11 and the second pattern layer PTL2.

That is, each of the first substrate 11 and the second pattern layer PTL2 may be made of a material with a lower refractive index than that of the first pattern layer PTL1.

Accordingly, the first substrate 11, the first pattern layer PTL1, and the second pattern layer PTL2 may be configured to be sequentially stacked in this order such that a low refractive index layer, a high refractive index layer, and a low refractive index layer are sequentially stacked in this order.

The first pattern structure PTP1 may be formed to have a concavo-convex pattern.

In one example, the first pattern structure PTP1 may be formed as a concavo-convex pattern of each of various shapes such as a hemisphere, an oval, a triangular pyramid, or a square pyramid. However, embodiments of the present disclosure are not limited thereto.

The second pattern structure PTP2 may be formed to have a trench pattern.

In one example, a height in the vertical direction of the trench pattern of the second pattern structure PTP2 may be greater than a width in the left-right direction thereof.

Accordingly, the second pattern structure PTP2 may be formed to have a high aspect ratio. The second pattern structure PTP2 may be formed to have a higher aspect ratio than that of the first pattern structure PTP1.

The second pattern structure PTP2 may have roughly a rectangle cross-sectional shape. However, embodiments of the present disclosure are not limited thereto.

The height of the second pattern structure PTP2 may be greater than a height of the first pattern structure PTP1.

Accordingly, a top of the second pattern structure PTP2 may be located closer to a bottom of the second active layer ACT2 of the second thin-film transistor TFT2 than a top of the first pattern structure PTP1 may be.

In this way, the second pattern structure PTP2 is formed to have a relatively larger height than that of the first pattern structure PTP1, and thus intensively reduces direct irradiation of light incident in an oblique direction through the lower surface of the first substrate 11 into the active layer.

Accordingly, the second pattern structure PTP2 may be formed at a border between adjacent ones of the pixels P, or at a border between adjacent ones of the sub-pixels SP1, SP2, and SP3.

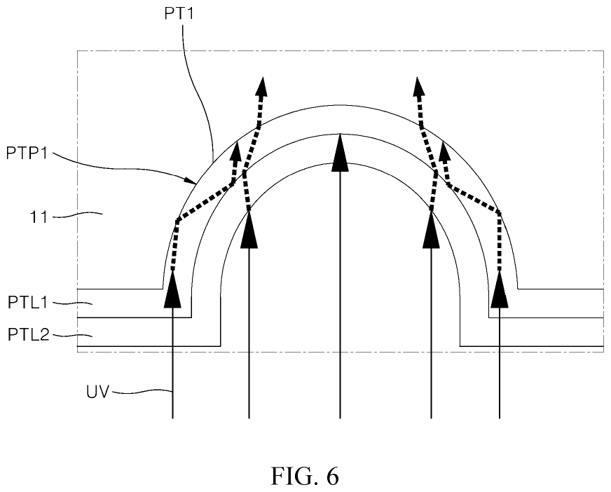

Referring to FIG. 6, the first pattern structure PTP1 may intensively absorb light incident from a position under the first substrate 11 in a perpendicular direction thereto.

While the ultraviolet light passes through the first pattern structure PTP1 as a stack structure of the low refractive index layer/high refractive index layer/low refractive index layer as previously described, a portion of the ultraviolet light is diffusely reflected, thereby changing a direction of the ultraviolet light which may be directed toward the active layer.

In addition, while the ultraviolet light passes through the first pattern structure PTP1, a portion of the ultraviolet light may be totally reflected within the first pattern layer PTL1 and may travel within the first pattern layer PTL1.

In this way, the ultraviolet light may be diffusely or totally reflected in the first pattern structure PTP1 such that a travel path thereof is increased. While the UV light is traveling along the increased light travel path, the UV light may be absorbed and extinguished by and in the first pattern layer PTL1.

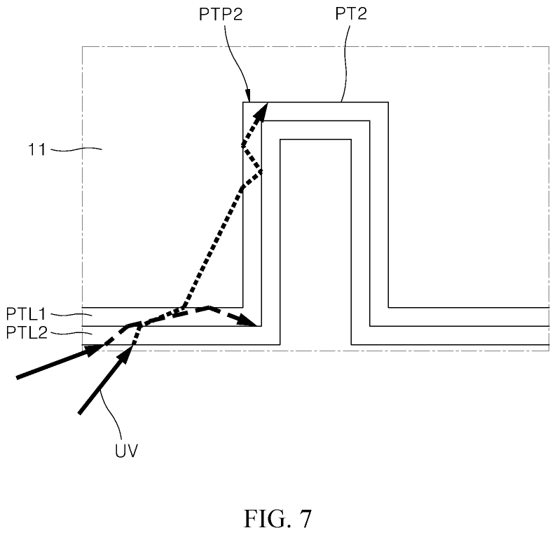

Referring to FIG. 7, the second pattern structure PTP2 may intensively absorb the light incident from a position under the first substrate 11 in a specific diagonal direction.

While the ultraviolet light passes through the second pattern structure PTP2 as a stack structure of the low refractive index layer/high refractive index layer/low refractive index layer as previously described, a portion of the ultraviolet light may be diffusely reflected, thereby changing a direction of the ultraviolet light which may be directed toward the active layer.

In addition, while the ultraviolet light passes through the second pattern structure PTP2, a portion of the ultraviolet light may be totally reflected within the second pattern layer PTL2 and may travel within the first pattern layer PTL2.

In particular, since the second pattern structure PTP2 is formed to have a larger height than that of the first pattern structure PTP1, a travel path along which light passes through the second pattern structure PTP2 may be further increased.

Additionally, since the second pattern structure PTP2 is formed to have a larger height than that of the first pattern structure PTP1, the second pattern structure PTP2 may more effectively absorb and extinguish not only light incident in the perpendicular direction to the lower surface of the substrate but also light incident in the diagonal direction thereto.

In this way, the ultraviolet light may be diffusely reflected or totally reflected in the second pattern structure PTP2 such that the UV light has a further increased travel path therein. Thus, while travelling along the further increased light travel path, the UV ray may be absorbed and extinguished by and in the second pattern layer PTL2.

In other words, a shape itself of each of the first pattern structure PTP1 and the second pattern structure PTP2 as formed in the above manner may increase a surface area of the lower surface of the first substrate 11, such that the travel path of the ultraviolet light may be increased.

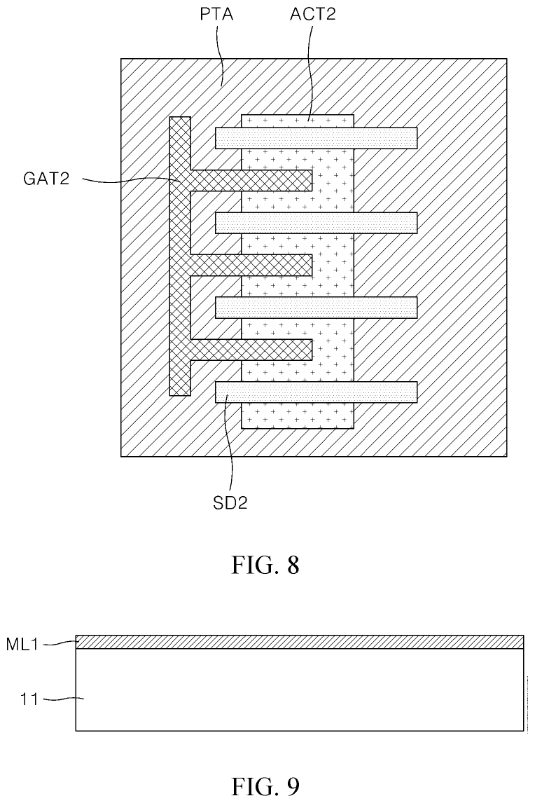

Referring to FIG. 8, the patterned area PTA formed in this way may be positioned to overlap with the second active layer ACT2 disposed on top of the patterned area PTA and at the same time, may be formed to have a larger area than that of the second active layer ACT2 to surround the second active layer ACT2. Thus, the patterned area PTA may effectively absorb the ultraviolet light incident from a position under the second active layer ACT2 in a perpendicular and/or diagonal manner thereto.

Hereinafter, with further reference to FIGS. 9 to 21, a process for forming the patterned area PTA in the first substrate 11 according to an embodiment of the present disclosure will be described.

A pattern formation method in each layer as described below may be performed using a photolithography process including deposition, photoresist application (PR) coating, exposure, development, etching, and photoresist stripping as a technique performed by a person skilled in the art. Thus, detailed descriptions thereof will be omitted.

For example, sputtering may be used when depositing a metal material. PE CVD (Plasma Enhanced Chemical Vapor Deposition) may be used when depositing a semiconductor or an insulating film. One of dry etching and wet etching may be selected depending on a type of a material.

Referring to FIG. 9, a first metal film ML1 may be deposited on the first substrate 11.

The first metal film ML1 may include one or more metals among copper (Cu), chromium (Cr), aluminum (AL), and nickel (Ni).

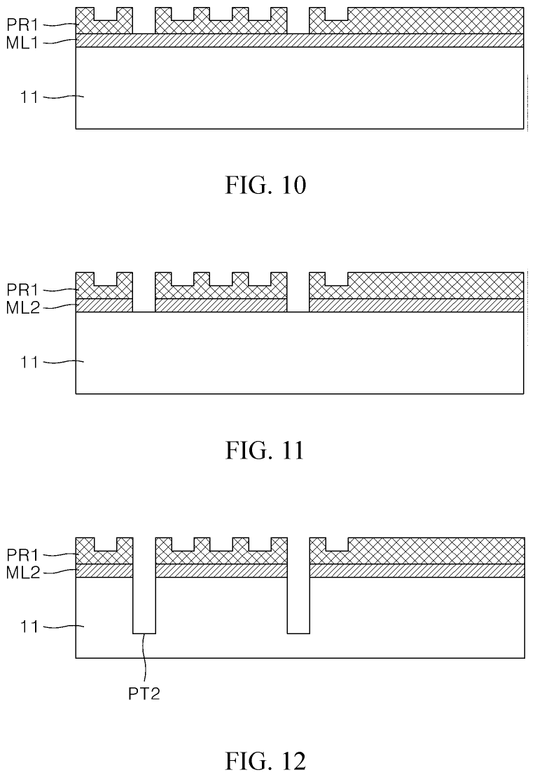

Referring to FIG. 10, a first photoresist pattern PR1 may be coated on the first metal film ML1.

The first photoresist pattern PR1 may be formed to have a pattern in which an area corresponding to the second pattern PT2 to be formed in the first substrate 11 is opened.

Accordingly, the first metal film ML1 may be exposed to an outside through the opened area of the first photoresist pattern PR1.

When the first photoresist pattern PR1 is coated on the first substrate 11, the first photoresist pattern PR1 may be formed in a patterned manner so that an area corresponding to the first pattern PT1 to be formed which will be described later is depressed.

Referring to FIG. 11, a portion of the first metal film ML1 exposed through the opened area of the first photoresist pattern PR1 may be etched away using wet etching.

As the first metal film ML1 is etched away in this way, the first metal film ML1 may be converted to a second metal film ML2 that exposes a partial area of the first substrate 11 to the outside.

Referring to FIG. 12, a portion of the first substrate 11 in an area corresponding to the opened area of each of the first photoresist pattern PR1 and the second metal film ML2 may be etched away using dry etching.

In this case, the etching scheme may a deep reactive ion etching (DRIE) scheme.

When using the deep reactive ion etching (DRIE), a pattern with a high aspect ratio may be formed while anisotropic etching is performed.

The high aspect ratio pattern formed in this way may be deeply depressed in the first substrate 11 in a perpendicular manner to the lower surface of the first substrate. Thus, the second pattern PT2 in which the height in the vertical direction is greater than the width in the left-right direction may be defined in the first substrate 11.

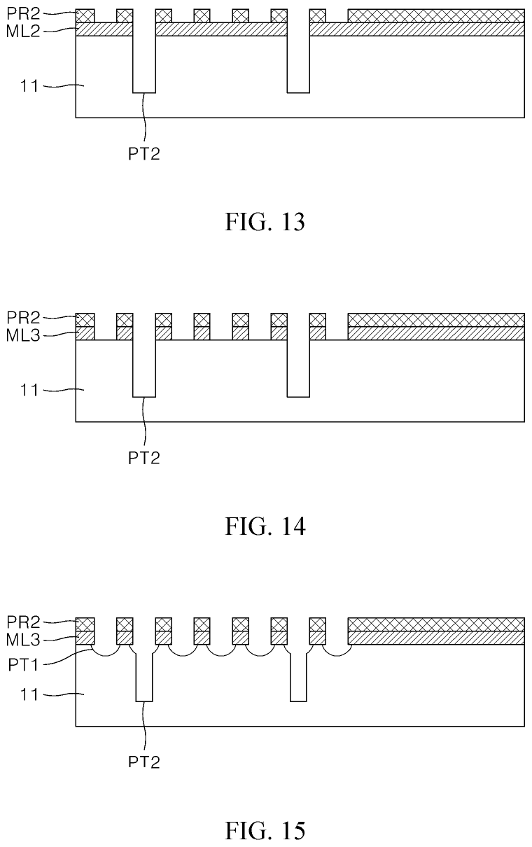

Referring to FIG. 13, the first photoresist pattern PR1 may be converted to a second photoresist pattern PR2 via an ashing process that removes a portion of the first photoresist pattern PR1.

Since the first photoresist pattern PR1 has already been patterned, the portion thereof has been removed in the ashing process, such that the first photoresist pattern PR1 may be converted to the second photoresist pattern PR2 exposing a partial area of the second metal film ML2 to the outside.

In this case, the exposed partial area of the second metal film ML2 may be an area corresponding to the first pattern PT1 to be formed.

Referring to FIG. 14, a portion of the second metal film ML2 exposed through the opened area of the second photoresist pattern PR2 may be etched away using wet etching.

As the second metal film ML2 is etched in this way, the second metal film ML2 may be converted into a third metal film ML3 that exposes a partial area of the first substrate 11 to the outside.

Referring to FIG. 15, a portion of the first substrate 11 in an area corresponding to the opened area of each of the second photoresist pattern PR2 and the third metal film ML3 may be etched away using wet etching.

For example, the wet etching may be performed using a HF-based diluted etchant or BOE solution.

As the portion of the first substrate 11 in the area corresponding to the opened area of each of the first photoresist pattern PR1 and the second metal film ML2 is etched away, the first pattern PT1 may be formed.

In this case, the first pattern PT1 formed using the wet etching process as an isotropic etching process may be formed to have a low aspect ratio.

Accordingly, the first pattern PT1 may be formed in a shape in which the height in the vertical direction is smaller than the width in the left-right direction.

Additionally, the second pattern PT2 which has already been formed in the previous process may be subjected to surface treatment during the wet etching process in which the first pattern PT1 is formed.

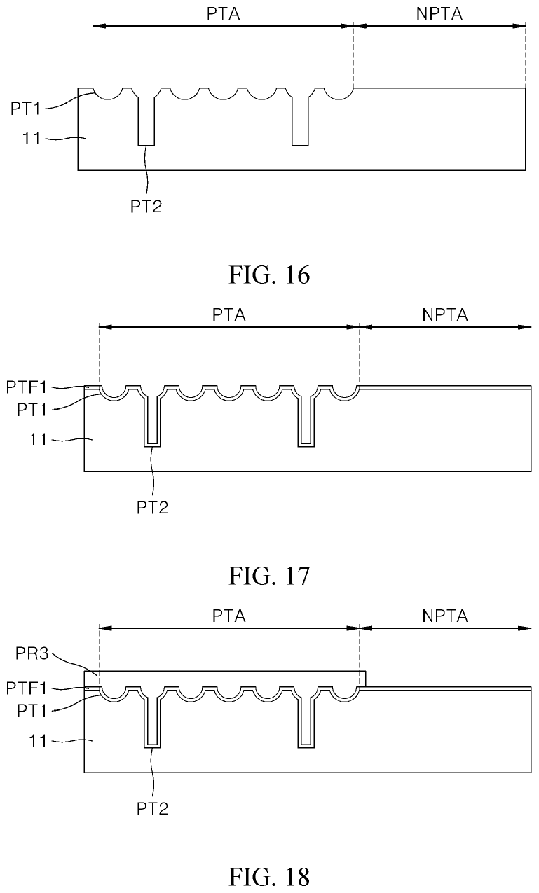

Referring to FIG. 16, the second photoresist pattern PR2 may be removed in a strip process and the third metal film ML3 may be removed in an etching process.

Accordingly, the patterned area PTA in which the first pattern PT1 and the second pattern PT2 are individually formed, and the non-patterned area NPTA may be individually in the first substrate 11.

Referring to FIG. 17, a first pattern film PTF1 may be deposited on an entire surface of the first substrate 11 in a conformal manner.

For example, the first pattern film PTF1 may include ITO.

Referring to FIG. 18, a third photoresist pattern PR3 may be coated on the patterned area PTA in a corresponding manner thereto.

In this case, the third photoresist pattern PR3 may be formed to have a pattern to cover the patterned area PTA but not to expose the non-patterned area NPTA so as to be exposed to the outside.

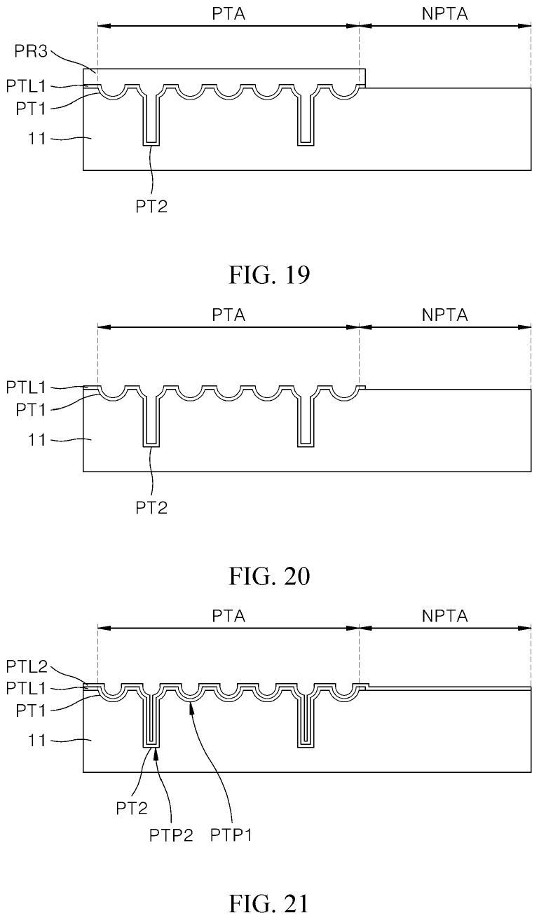

Referring to FIG. 19, a portion of the first pattern film PTF1 not covered with the third photoresist pattern PR3 so as to be exposed may be etched and removed using wet etching.

As the portion of the first pattern film PTF1 corresponding to the non-patterned area NPTA is removed in this way, the first pattern layer PTL1 covering the patterned area PTA may be formed.

Next, referring to FIG. 20, the third photoresist pattern PR3 may be removed through a strip process.

Accordingly, the first pattern layer PTL1 may be formed in the patterned area PTA and on the first substrate 11.

Next, referring to FIG. 21, the second pattern layer PTL2 may be deposited on the first pattern layer PTL1.

For example, the second pattern layer PTL2 may include SiO₂.

In this case, the second pattern layer PTL2 may be formed on an entire surface of the first substrate 11 to cover not only the patterned area PTA but also the non-patterned area NPTA.

The second pattern layer PTL2 includes the same material as that of the first substrate 11. In this case, even when the second pattern layer is formed in the non-patterned area NPTA, the transmittance of the first substrate 11 may not be reduced.

However, according to an embodiment, an additional process of removing the second pattern layer PTL2 located in the non-patterned area NPTA may be performed.

In the display device according to an embodiment of the present disclosure as described above, an amount of ultraviolet rays irradiated to the active layers of some of the thin-film transistors may be reduced due to the patterned area formed in an area of the lower surface of the substrate corresponding to some of the thin-film transistors. Thus, the negative shift of the threshold voltage of each of some of the thin-film transistors may be reduced.

In addition, in the display device according to an embodiment of the present disclosure, the patterned area may be formed not in the entire lower surface of the substrate, but in a partial area thereof. Thus, the decrease in transmittance of the transparent display device due to the presence of the patterned area may be minimized.

In addition, in the display device according to an embodiment of the present disclosure, the patterned area formed in the partial area of the lower surface of the substrate may block external ultraviolet rays, such that there is no need to attach a separate UV-blocking member to an entire area of the substrate. Thus, a scheme of repairing the defective pixel by irradiating the ultraviolet laser through the bottom of the substrate may be freely used without any special restrictions.

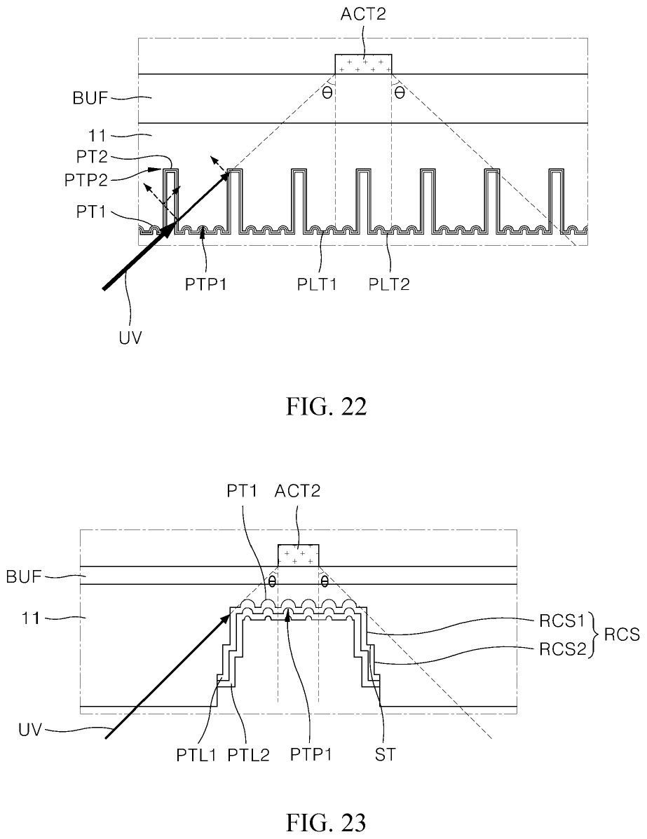

Hereinafter, with reference to FIGS. 22 to 26, additional embodiments of the patterned area PTA of the first substrate 11 of the present disclosure will be described.

Referring to FIG. 22, the buffer layer BUF may be disposed on the first substrate 11 on which the first pattern structure PTP1 and the second pattern structure PTP2 are formed in the lower surface thereof, and the second active layer ACT2 may be disposed on the buffer layer.

As previously described, when the patterned area PTA is formed on the entire surface of the first substrate 11, a significant portion of the ultraviolet rays may be blocked thereby, while transmittance may be reduced in a transparent display device.

Accordingly, it is preferable that the patterned area PTA may be formed by selectively patterning the partial area of the first substrate 11 such that patterned area PTA overlaps the active layer of each of some of the thin-film transistors that require protection from the ultraviolet rays.

In this case, when an area where the patterned area PTA is formed is too small, it may be difficult for the patterned area to block the ultraviolet rays incident from a position under the lower surface of the first substrate 11 in a diagonal direction of a predefined angle θ or greater.

Accordingly, the area where the patterned area PTA is formed may be increased in order to block the ultraviolet rays incident in the diagonal direction of the predefined angle θ or greater. However, in this case, the transmittance of the transparent display device may be reduced.

In addition, in order to block the ultraviolet rays incident in a diagonal direction of the predefined angle θ or greater, the height of the second pattern PT2 may be further increased so that the aspect ratio of the second pattern PT2 is further increased. However, in this case, a process time or cost may increase.

Therefore, referring to FIG. 23, the patterned area PTA of the first substrate 11 of the display device 1 according to an embodiment of the present disclosure may be formed to include a recess RCS depressed toward the second active layer ACT2.

The recess RCS may be positioned to overlap the second active layer ACT2 in the vertical direction, and may be formed to have a width in the left-right direction that is larger than the width in the left-right direction of the second active layer ACT2.

The recess RCS may include a first recess RCS1 as an upper recess and a second recess RCS2 located under the first recess RCS1.

A width in the left-right direction of the first recess RCS1 may be smaller than a width in the left-right direction of the second recess RCS2.

Accordingly, a step ST may be formed at a boundary between the first recess RCS1 and the second recess RCS2.

A plurality of first patterns PT1 may be formed on an upper surface of the recess RCS.

However, embodiments of the present disclosure are not limited thereto, and a plurality of second patterns PT2 may be formed on the upper surface of the recess RCS.

The first pattern layer PTL1 and the second pattern layer PTL2 may be sequentially stacked under the upper surface of the recess RCS.

That is, the first pattern layer PTL1 and the second pattern layer PTL2 may be disposed on an inner lower surface of the recess RCS.

In this case, the first pattern layer PTL1 and the second pattern layer PTL2 may be formed to extend to an inner surface of the recess RCS.

For example, the first pattern layer PTL1 and the second pattern layer PTL2 may extend to cover the inner surface of the first recess RCS1 and the inner surface of the second recess RCS2.

The first pattern structure PTP1 composed of the first pattern PT1 of the first substrate 11, the first pattern layer PTL1, and the second pattern layer PTL2 formed in this way may be formed on the upper surface of the recess RCS.

Accordingly, the first pattern structure PTP1 may be disposed closer to the lower surface of the second active layer ACT2 than the second pattern structure PTP2 may be.

For example, in an embodiment according to FIG. 22, the first pattern structure PTP1 and the second pattern structure PTP2 are formed in the lower surface of the first substrate 11. Thus, in order to block the ultraviolet rays incident in the diagonal direction of the predefined angle θ or greater, the width in the left-right direction of the patterned area PTA should be increased.

Alternatively, as in the embodiment according to FIG. 23, the recess RCS is formed in the first substrate 11, and then, the first pattern structure PTP1 is formed on the upper surface of the recess RCS. Thus, even though the width in the left-right direction of the recess RCS corresponding to the patterned area PTA, the patterned area may effectively block the ultraviolet rays incident in the diagonal direction of a specific angle θ or greater.

Further, because the step ST formed in the recess RCS may further increase the path along which the ultraviolet light travels, a shape of the recess RCS also has the effect of further increasing the travel path of ultraviolet light.

Therefore, according to an embodiment referring to FIG. 23, even when the width in the left-right direction, thus, an area size of the patterned area PTA is reduced, not only may ultraviolet light be effectively absorbed and blocked by the patterned area, but also the transmittance of the transparent display device may be sufficiently secured.

A height of the recess RCS may be preferably at least 50% of a height of the first substrate 11.

More preferably, the height of the recess RCS is formed may be at least 80% of the height of the first substrate 11. The height of the recess may be set to a value at which the threshold voltage shift (Vth shift) due to the back body effect does not occur in the thin-film transistor located on top of the recess RCS.

As the height of the recess RCS is set as described above, a distance between the first pattern structure PTP1 formed on the upper surface of the recess RCS and the second active layer ACT2 may be small as possible, such that a size of the patterned area PTA may be reduced.

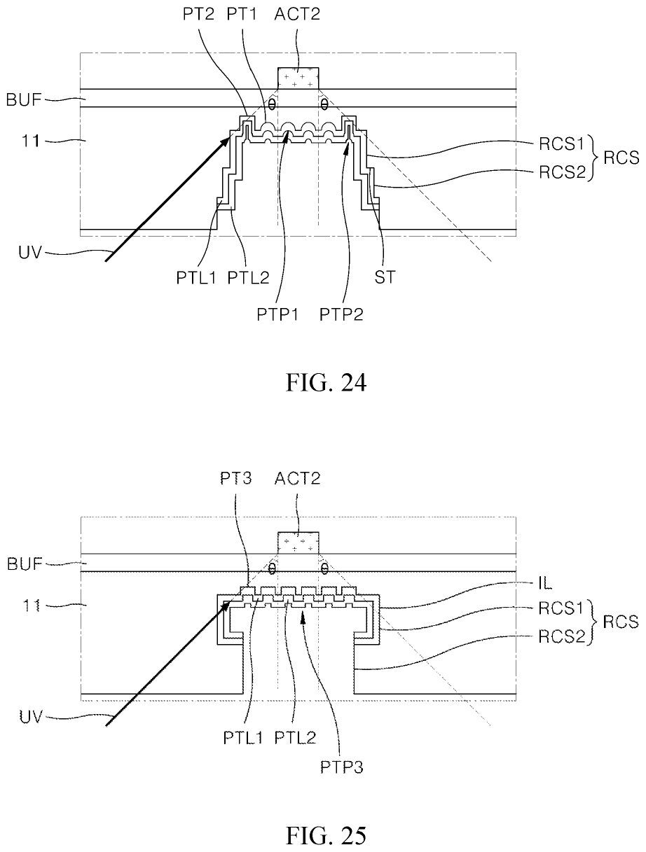

Referring to FIG. 24, the second pattern structure PTP2 in addition to the first pattern structure PTP1 may be formed on the upper surface of the recess RCS.

In this case, the second pattern structure PTP2 may be disposed at both opposing ends of the upper surface of the recess RCS.

Because the second pattern structure PTP2 has a higher aspect ratio than that of the first pattern structure PTP1, the second pattern structure PTP2 may be disposed to be closer to the second active layer ACT2 than the first pattern structure PTP1 may be.

Therefore, the second pattern structure PTP2 which has a larger height may be disposed at both opposing ends of the upper surface of the recess RCS. Thus, even when the width in the left-right direction of the recess RCS corresponding to the patterned area PTA is further reduced, the patterned area may effectively block the ultraviolet rays incident in a diagonal direction of the predefined angle θ or greater.

Referring to FIG. 25, the patterned area PTA of the first substrate 11 of the display device 1 according to an embodiment of the present disclosure may be formed to include the recess RCS recessed toward the second active layer ACT2.

The recess RCS may be positioned to overlap the second active layer ACT2 in the vertical direction, and may be formed to have the width in the left-right direction that is larger than the width in the left-right direction of the second active layer ACT2.

The recess RCS may include the first recess RCS1 as an upper recess and a second recess RCS2 as a lower recess located under the first recess RCS1.

The width in the left-right direction of the first recess RCS1 may be formed to be larger than the width in the left-right direction of the second recess RCS2.

Accordingly, a lateral cut IL may be formed in a side surface of the first recess RCS1, and this lateral cut IL may act as a step.

Due to the lateral cut IL formed in the recess RCS, the path along which the ultraviolet light travels may be further increased. Thus, the shape of the recess RCS also has the effect of further increasing the travel path of the ultraviolet light.

A plurality of third patterns PT3 may be formed on the upper surface of the recess RCS.

For example, the third pattern PT3 may be formed using a cryogenic etch process.

The cryogenic etch process may improve a loading effect as a phenomenon in which an etch rate varies depending on an etched area.

The third pattern PT3 formed in this way may be formed to have a concavo-convex pattern shape with a high aspect ratio.

The first pattern layer PTL1 and the second pattern layer PTL2 may be sequentially stacked under the upper surface of the recess RCS.

That is, the first pattern layer PTL1 and the second pattern layer PTL2 may be disposed on an inner lower surface of the recess RCS.

In this case, the first pattern layer PTL1 and the second pattern layer PTL2 may be formed to extend to the inner surface of the recess RCS.

For example, the first pattern layer PTL1 and the second pattern layer PTL2 may extend to cover the inner surface of the first recess RCS1 and the inner surface of the second recess RCS2.

The third pattern PTP3 composed of the first pattern PT1 of the first substrate 11, the first pattern layer PTL1, and the second pattern layer PTL2 formed in this way may be formed on the upper surface of the recess RCS.

Accordingly, the third pattern PTP3 may be disposed closer to the lower surface of the second active layer ACT2.

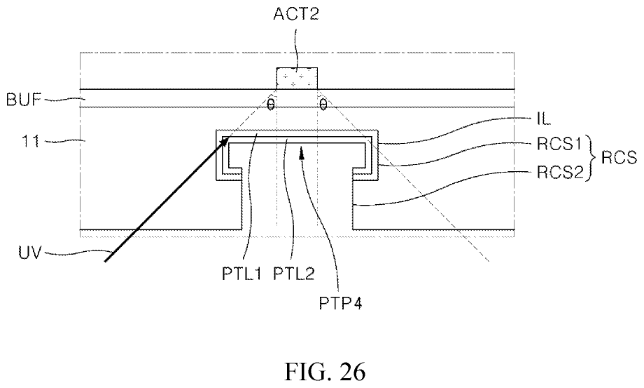

Referring to FIG. 26, the patterning process is not performed on the upper surface of the recess RCS, and the first pattern layer PTL1 and the second pattern layer PTL2 may be sequentially stacked under the upper surface of the recess RCS.

The first pattern layer PTL1 and the second pattern layer PTL2 may constitute a fourth pattern PTP4.

The first pattern layer PTL1 may be made of an opaque metal material.

The first pattern layer PTL1 is made of the opaque metal material. Thus, even though a pattern is not formed in the recess RCS of the first substrate 11 in a separate patterning process, the first pattern layer PTL1 made of the opaque metal material may block the ultraviolet rays.

In the embodiment according to FIG. 26, even when the area size of the patterned area PTA is reduced due to the formation of the recess RCS, the ultraviolet rays to be incident onto the second active layer ACT2 in a diagonal direction greater than or equal to the predefined angle θ may be sufficiently effectively blocked by the first pattern layer PTL1.

Therefore, since the area occupied with the opaque first pattern layer PTL1 in a total area of the display area AA is not large, the decrease in the transmittance of the transparent display device may be insignificant.

Therefore, in the embodiment according to FIG. 26, the separate patterning process is not performed on the recess RCS, thereby reducing the overall process time and process cost.

A display device according to some aspects and embodiments of the present disclosure as described above may be described as follows.

A first aspect of the present disclosure provides a display device comprising: a substrate including a plurality of pixels, each including a plurality of sub-pixels; and a first thin-film transistor and a second thin-film transistor included in each of the sub-pixels, wherein a non-patterned area vertically overlapping the first thin-film transistor and a patterned area vertically overlapping the second thin-film transistor are formed in a lower surface of the substrate.

In accordance with some embodiments of the display device of the first aspect, the display device further comprises a light-blocking layer disposed between the substrate and the first and second thin-film transistors, wherein the light-blocking layer is positioned to overlap the first thin-film transistor in the vertical direction, but not to overlap the second thin-film transistor in the vertical direction.

In accordance with some embodiments of the display device of the first aspect, a portion of the lower surface of the substrate corresponding to the patterned area has a depressed shape depressed toward the second thin-film transistor.

In accordance with some embodiments of the display device of the first aspect, the patterned area includes a first pattern and/or a second pattern, wherein a height of the second pattern is greater than a height of the first pattern.

In accordance with some embodiments of the display device of the first aspect, the first pattern has a concavo-convex pattern, wherein the second pattern has a trench pattern having a height in the vertical direction greater than a width in a left-right direction thereof.

In accordance with some embodiments of the display device of the first aspect, the second pattern is further disposed between adjacent ones of the pixels or between adjacent ones of the sub-pixels.

In accordance with some embodiments of the display device of the first aspect, the first thin-film transistor is a driving thin-film transistor, wherein the second thin-film transistor is a scanning thin-film transistor and/or a sensing thin-film transistor.

In accordance with some embodiments of the display device of the first aspect, the display device further comprises a gate driver disposed on an upper surface of the substrate, wherein the patterned area is further disposed in the lower surface of the substrate and in an area vertically overlapping the gate driver.

A second aspect of the present disclosure provides a display device comprising: a substrate including a display area and a non-display area; a plurality of sub-pixels arranged in the display area; and a plurality of thin-film transistor included in each of the sub-pixels, wherein a lower surface of the substrate includes a patterned area formed by selectively patterning a portion of the lower surface in an area corresponding to at least one of the plurality of thin-film transistors.

In accordance with some embodiments of the display device of the second aspect, the display device further comprises a gate driver disposed on an upper surface of the non-display area of the substrate, wherein the lower surface of the substrate further includes a patterned area formed by patterning a portion of the lower surface in an area vertically overlapping the gate driver.

In accordance with some embodiments of the display device of the second aspect, the display device further comprises a light-blocking layer disposed between the substrate and the plurality of thin-film transistors, wherein the light-blocking layer is positioned so as not to overlap the patterned area in the vertical direction.

In accordance with some embodiments of the display device of the second aspect, the display device further comprises: a first pattern layer disposed on the lower surface of the substrate and in the patterned area; and a second pattern layer disposed on the lower surface of the first pattern layer, wherein a refractive index of each of the substrate and a second pattern layer is lower than a refractive index of the first pattern layer.

In accordance with some embodiments of the display device of the second aspect, the first pattern layer includes at least one of indium tin oxide (ITO), indium zinc oxide (IZO), and zinc oxide (ZnO).

In accordance with some embodiments of the display device of the second aspect, the substrate is made of glass, wherein the second pattern layer includes silicon oxide.

In accordance with some embodiments of the display device of the second aspect, the thin-film transistor includes an active layer, wherein the patterned area includes a recess positioned to overlap the active layer in the vertical direction and recessed toward the active layer, wherein the first pattern layer and the second pattern layer are disposed on an inner surface of the recess.

In accordance with some embodiments of the display device of the second aspect, the recess includes a first recess and a second recess disposed under the first recess, wherein a width in a left-right direction of the first recess is smaller than a width in a left-right direction of the second recess so that a step is formed at a boundary between the first recess and the second recess.

In accordance with some embodiments of the display device of the second aspect, the recess includes a first recess and a second recess disposed under the first recess, wherein a lateral cut is formed in an inner side surface of the first recess such that a width in a left-right direction of the first recess is larger than a width in a left-right direction of the second recess.

In accordance with some embodiments of the display device of the second aspect, a first pattern and/or a second pattern are disposed on an upper surface of the recess, wherein the second pattern is closer to the active layer than the first pattern is.

In accordance with some embodiments of the display device of the second aspect, the second pattern is disposed at both opposing ends of the upper surface of the recess.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents

1. A display device comprising:
a substrate including a plurality of pixels, each including a plurality of sub-pixels; and
a first thin-film transistor and a second thin-film transistor included in each of the sub-pixels, and
wherein a non-patterned area vertically overlapping the first thin-film transistor and a patterned area vertically overlapping the second thin-film transistor are formed in a lower surface of the substrate.

2. The display device of claim 1, wherein the display device further comprises a light-blocking layer disposed between the substrate and the first and second thin-film transistors, and
wherein the light-blocking layer is positioned to overlap the first thin-film transistor in the vertical direction, but not to overlap the second thin-film transistor in the vertical direction.

3. The display device of claim 1, wherein a portion of the lower surface of the substrate corresponding to the patterned area comprises a depressed shape depressed toward the second thin-film transistor.

4. The display device of claim 3, wherein the patterned area comprises at least one of a first pattern and a second pattern, and
wherein a height of the second pattern is greater than a height of the first pattern.

5. The display device of claim 4, wherein the first pattern has a concave-convex pattern, and
wherein the second pattern has a trench pattern having a height in the vertical direction greater than a width in a left-right direction thereof.

6. The display device of claim 4, wherein the second pattern is further disposed between adjacent ones of the pixels or between adjacent ones of the sub-pixels.

7. The display device of claim 1, wherein the first thin-film transistor is a driving thin-film transistor, and
wherein the second thin-film transistor is at least one of a scanning thin-film transistor and a sensing thin-film transistor.

8. The display device of claim 1, wherein the display device further comprises a gate driver disposed on an upper surface of the substrate, and
wherein the patterned area is further disposed in the lower surface of the substrate and in an area vertically overlapping the gate driver.

9. A display device comprising:
a substrate including a display area and a non-display area;
a plurality of sub-pixels arranged in the display area; and
a plurality of thin-film transistor included in each of the sub-pixels, and
wherein a lower surface of the substrate includes a patterned area formed by selectively patterning a portion of the lower surface in an area corresponding to at least one of the plurality of thin-film transistors.

10. The display device of claim 9, wherein the display device further comprises a gate driver disposed on an upper surface of the non-display area of the substrate, and
wherein the lower surface of the substrate further includes a patterned area formed by patterning a portion of the lower surface in an area vertically overlapping the gate driver.

11. The display device of claim 9, wherein the display device further comprises a light-blocking layer disposed between the substrate and the plurality of thin-film transistors, and
wherein the light-blocking layer is positioned so as not to overlap the patterned area in the vertical direction.

12. The display device of claim 9, wherein the display device further comprises:
a first pattern layer disposed on the lower surface of the substrate and in the patterned area; and
a second pattern layer disposed on the lower surface of the first pattern layer, and
wherein a refractive index of each of the substrate and a second pattern layer is lower than a refractive index of the first pattern layer.

13. The display device of claim 12, wherein the first pattern layer includes at least one of indium tin oxide (ITO), indium zinc oxide (IZO), and zinc oxide (ZnO).

14. The display device of claim 12, wherein the substrate is made of glass, and
wherein the second pattern layer includes silicon oxide.

15. The display device of claim 12, wherein the thin-film transistor includes an active layer,
wherein the patterned area includes a recess positioned to overlap the active layer in the vertical direction and recessed toward the active layer, and
wherein the first pattern layer and the second pattern layer are disposed on an inner surface of the recess.

16. The display device of claim 15, wherein the recess comprises a first recess and a second recess disposed under the first recess, and
wherein a width in a left-right direction of the first recess is smaller than a width in a left-right direction of the second recess so that a step is formed at a boundary between the first recess and the second recess.

17. The display device of claim 15, wherein the recess comprises a first recess and a second recess disposed under the first recess, and
wherein a lateral cut is formed in an inner side surface of the first recess such that a width in a left-right direction of the first recess is larger than a width in a left-right direction of the second recess.

18. The display device of claim 15, wherein at least one of a first pattern and a second pattern are disposed on an upper surface of the recess, and
wherein the second pattern is closer to the active layer than the first pattern is.

19. The display device of claim 18, wherein the second pattern is disposed at both opposing ends of the upper surface of the recess.
